(19) United States
(12) Patent Application Publication
(10) Pub. No.: US 2008/0083527 A1
(43) Pub. Date: Apr. 10, 2008

(54) Combined backlighting and heat-dissipating module for flat panel display

(75) Inventors: Alex Horng, Kaohsiung (TW); Te-Chen Liu, Kaohsiung (TW); Miyahara Masaharu, Kaohsiung (TW)

Correspondence Address: BIRCH STEWART KOLASCH & BIRCH, PO BOX 747, FALLS CHURCH, VA, 22040-0747, US

(73) Assignee: Sunonwealth Electric Machine Industry Co., Ltd.

(21) Appl. No.: 11/605,278

(22) Filed: Nov. 29, 2006

(30) Foreign Application Priority Data
Oct. 4, 2006 (TW) 95136854

(51) Int. Cl. H05K 7/20

(52) U.S. Cl. 165/80.3; 361/697; 165/121

(57) ABSTRACT

A combined backlighting and heat-dissipating module for a flat panel display includes a heat-dissipating plate, a cover plate and a cross-flow fan system. The heat-dissipating plate has a rear surface to form a plurality of thermal-exchanging channels and heat-dissipating fins. Each of the thermal-exchanging channels is formed between any two of the adjacent fins. The cover plate is provided on the rear surface of the heat-dissipating plate to cover the thermal-exchanging channels. The cross-flow fan system is arranged at inlet ends of the thermal-exchanging channels. In heat-dissipating operation, the cross-flow fan system drives a cooling airflow to enter the inlet ends of the thermal-exchanging channels and to exhaust it from outlet ends of the thermal-exchanging channels.

### BACKGROUND OF THE INVENTION

1. Field of the Invention

The present invention relates to a combined backlighting and heat-dissipating module for a flat panel display. Particularly, the present invention relates to the combined backlighting and heat-dissipating module having a cross-flow fan system for the flat panel display. More particularly, the present invention relates to the cross-flow fan system of the combined backlighting and heat-dissipating module drives a cooling airflow to pass through thermal-exchanging channels and heat-dissipating fins of a heat-dissipating plate.

2. Description of the Related Art

Referring initially to FIG. 1, a conventional backlighting and heat-dissipating module for use in the flat panel display typically includes a backlighting plate 91, a heat-dissipating plate 92, a pair of heat sink sets 93 and a plurality of heat-dissipating fans 94. The backlighting plate 91 provides a plurality of light emitting diodes (“LEDs”) arranged thereon, which are not shown in FIG. 1. The backlighting plate 91 is attached to a rear portion of a flat panel display (“FPD”) 90 so as to provide a light source which emits lights penetrating the flat panel display 90.

Typically, the heat-dissipating plate 92 is made from a metal such as aluminum or copper having a good thermal conductivity. In addition, the heat-dissipating plate 92 further provides a set of liquid circulating pipes 920 embedded therein. A coolant or other equivalent liquid may run along the liquid circulating pipes 920 for circulation while operating the backlighting and heat-dissipating module.

In assembling operation, one side of the heat-dissipating plate 92 is attached to a corresponding side of the backlighting plate 91 such that the metal and coolant can conduct waste heats generated from the LEDs of the backlighting plate 91. Mounted on opposite distal ends of the heat-dissipating plate 92 are the heat sink sets 93 each of which provides a plurality of air channels 930 extending in a longitudinal direction of the heat-dissipating plate 92. Further mounted on each of the heat sink sets 93 is the heat-dissipating fan 94 which has a fan wheel 940 to drive a cooling airflow. In this manner, the cooling air may be forced to run along each lengthwise direction of the air channels 930 of the corresponding heat sink set 93.

When illuminating the LEDs of the backlighting plate 91, heats generated from the LEDs must be conducted to the heat-dissipating plate 92 and the coolant contained in the liquid circulating pipes 920. Circulations of the heated coolant may create a convection of the heats for implementing liquid heat-dissipating operation. The heat may be conducted to the heat sink sets 93 and dissipated from the heat sink sets 93 into the ambient environment by the heat-dissipating fan 94 until the heated coolant has passed through a section of the liquid circulating pipes 920 located around the heat sink sets 93. In this manner, the heated coolant may be cooled and relatively contracted if the heats are dissipated properly. Accordingly, the low-temperature coolant may be automatically returned along the liquid circulating pipes 920 due to its circulation.

In general, a number of design limitations and drawbacks exist for the above flat panel display 90. By way of example, the heat sink sets 93 and the heat-dissipating fans 94 can only arranged at the opposite distal ends of the heat-dissipating plate 92 due to the fact that the flat panel display 90 or the backlighting plate 91 comes in a large-sized plate. Accordingly, the heat-dissipating fans 94 cannot drive a cooling airflow to pass through a center portion of the heat-dissipating plate 92 where the temperature is even relatively high. This results in different heat-dissipating efficiencies on the backlighting plate 91 or the heat-dissipating plate 92. If the waste heats are not properly dissipated from the center portion of the heat-dissipating plate 92, they may cause damage to the flat panel display 90.

To enhance the heat-dissipating efficiency of the backlighting and heat-dissipating backlighting module, there is a need for increasing the number of the heat sink sets 93 and the heat-dissipating fans 94. This results in an increased amount of noise when all of the heat-dissipating fans 94 are operated. Also, this further results in an increase of the overall cost of the backlighting and heat-dissipating module.

With regard to the problematic aspects naturally occurring during the use of the backlighting and heat-dissipating module, it cannot provide adequate cooling air if there is a failure of one or more of the heat-dissipating fans 94. Hence, there is a need for improving the conventional backlighting and heat-dissipating module for the flat panel display.

As is described in greater detail below, the present invention intends to provide a combined backlighting and heat-dissipating module having a cross-flow fan system arranged at a side of a heat-dissipating plate to drive a cooling airflow to pass through thermal-exchanging channels and heat-dissipating fins which are provided on a rear surface of the heat-dissipating plate. A cover plate is further provided on the rear surface of the heat-dissipating plate to cover the thermal-exchanging channels for guiding the cooling airflow in such a way as to mitigate and overcome the above problem.

### SUMMARY OF THE INVENTION

The primary objective of this invention is to provide a combined backlighting and heat-dissipating module for a flat panel display, wherein a cross-flow fan system arranged at a side of a heat-dissipating plate to drive a cooling airflow to pass through thermal-exchanging channels and heat-dissipating fins which are provided on a rear surface of the heat-dissipating plate. Accordingly, the total heat-dissipating efficiency of the combined backlighting and heat-dissipating module is increased.

The secondary objective of this invention is to provide the combined backlighting and heat-dissipating module for use in the flat panel display, wherein a cover plate is provided on the rear surface of the heat-dissipating plate to cover the thermal-exchanging channels for guiding the cooling airflow. Accordingly, the highly heat-dissipating efficiency of the combined backlighting and heat-dissipating module is carried out.

The combined backlighting and heat-dissipating module in accordance with an aspect of the present invention includes a heat-dissipating plate, at least one cover plate and a cross-flow fan system. The heat-dissipating plate has a rear surface to form a plurality of thermal-exchanging channels and heat-dissipating fins. Each of the thermal-exchanging channels is formed between any two of the adjacent fins. The cover plate is provided on the rear surface of the heat-dissipating plate to cover the thermal-exchanging channels. The cross-flow fan system is arranged at inlet ends of the thermal-exchanging channels. In heat-dissipating operation, the cross-flow fan system drives a cooling airflow to enter the inlet ends of the thermal-exchanging channels and to exhaust it from outlet ends of the thermal-exchanging channels.

In a separate aspect of the present invention, the cover plate is integrally formed on one of the heat-dissipating fin.

In a further separate aspect of the present invention, a convectional slit is formed between any two of the adjacent cover plates for adjusting air pressure in the thermal-exchanging channels.

In a yet further separate aspect of the present invention, the cover plate is integrally formed on a housing of the cross-flow fan system.

In a yet further separate aspect of the present invention, two of the cross-flow fan systems are arranged at air inlet ends and air outlet ends of the thermal-exchanging channels respectively.

Further scope of the applicability of the present invention will become apparent from the detailed description given hereinafter. However, it should be understood that the detailed description and specific examples, while indicating preferred embodiments of the invention, are given by way of illustration only, since various will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is an assembled perspective view illustrating a conventional backlighting and heat-dissipating module combined with a flat panel display in accordance with the prior art;

FIG. 2 is an exploded perspective view illustrating a combined backlighting and heat-dissipating module in accordance with a first embodiment of the present invention;

FIG. 3 is a rear plan view illustrating the combined backlighting and heat-dissipating module in accordance with the first embodiment of the present invention;

FIG. 4 is a cross-sectional view, taken along line 4-4 in FIG. 3, illustrating the combined backlighting and heat-dissipating module in accordance with the first embodiment of the present invention;

FIG. 5 is a cross-sectional view, taken along line 5-5 in FIG. 3, illustrating the combined backlighting and heat-dissipating module in accordance with the first embodiment of the present invention;

FIG. 6 is a fragmental perspective view illustrating the combined backlighting and heat-dissipating module in accordance with a second embodiment of the present invention;

FIG. 7 is a cross-sectional view, taken along line 7-7 in FIG. 6, illustrating the combined backlighting and heat-dissipating module in accordance with the second embodiment of the present invention;

FIG. 8 is a perspective view illustrating the combined backlighting and heat-dissipating module in accordance with a third embodiment of the present invention; and

FIG. 9 is a cross-sectional view, taken along line 9-9 in FIG. 8, illustrating the combined backlighting and heat-dissipating module in accordance with the third embodiment of the present invention.

### DETAILED DESCRIPTION OF THE INVENTION

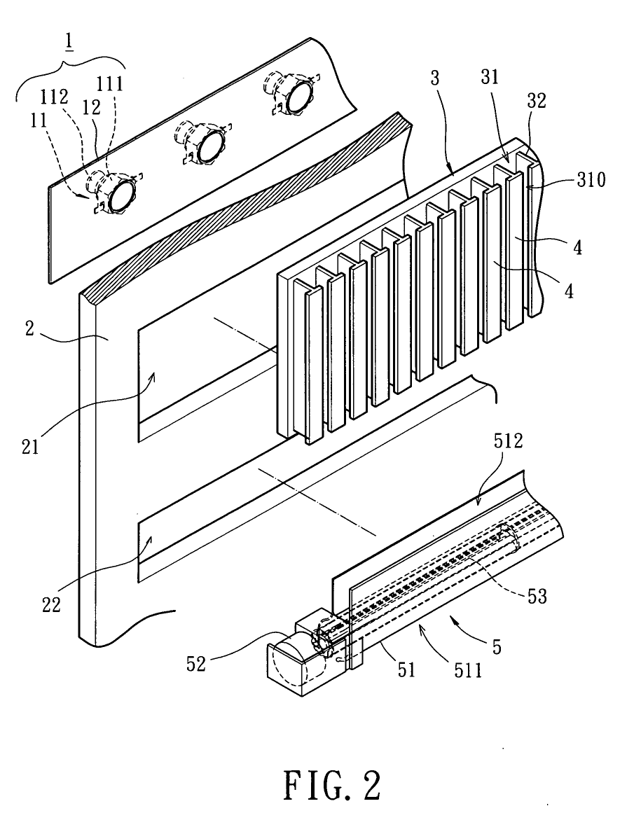

Referring now to FIGS. 2 through 5, views of a combined backlighting and heat-dissipating module in accordance with the first embodiment of the present invention are illustrated. In general, the combined backlighting and heat-dissipating module includes a back light unit designated numeral 1, a frame plate designated numeral 2, a heat-dissipating plate designated numeral 3, a plurality of cover plates designated numeral 4 and a cross-flow fan system designated numeral 5. The back light unit 1 and the heat-dissipating plate 2 are essentially assembled to form the combined backlighting and heat-dissipating module which is combined with a rear surface of a flat panel display. In a preferred embodiment, the combined backlighting and heat-dissipating module of the present invention is applied to the flat panel display which is generally selected from a liquid crystal display (“LCD”) or a plasma display panel (“PDP”).

Still referring to FIGS. 2 through 4, the back light unit 1 is arranged in the frame plate 2, and is attached to a front surface of the heat-dissipating plate 3. In this way, the back light unit 1 is in thermal communication with the heat-dissipating plate 3 such that heat generated from the back light unit 1 is conducted to the heat-dissipating plate 3. The cross-flow fan system 5 is arranged at a bottom side of the heat-dissipating plate 3 so that an upright cooling airflow driven by the cross-flow fan system 5 can pass through the heat-dissipating plate 3.

Constructions of the back light unit 1 shall be described in detail, with reference to FIGS. 2 and 4. The back light unit 1 includes at least one backlighting unit 11 and a printed circuit board 12 electrically connected thereto. The backlighting unit 11 can be actuated to provide a light source for the flat panel display. The backlighting unit 11 has a mounting seat 111 and a light component 112 mounted thereon. Preferably, the mounting seat 111 is made from a metal such as aluminum, copper, gold, silver or alloy thereof having a good thermal conductivity. In this manner, heats generated from the light component 112 can be conducted to the heat-dissipating plate 3 which is mechanically connected with the mounting seat 111.

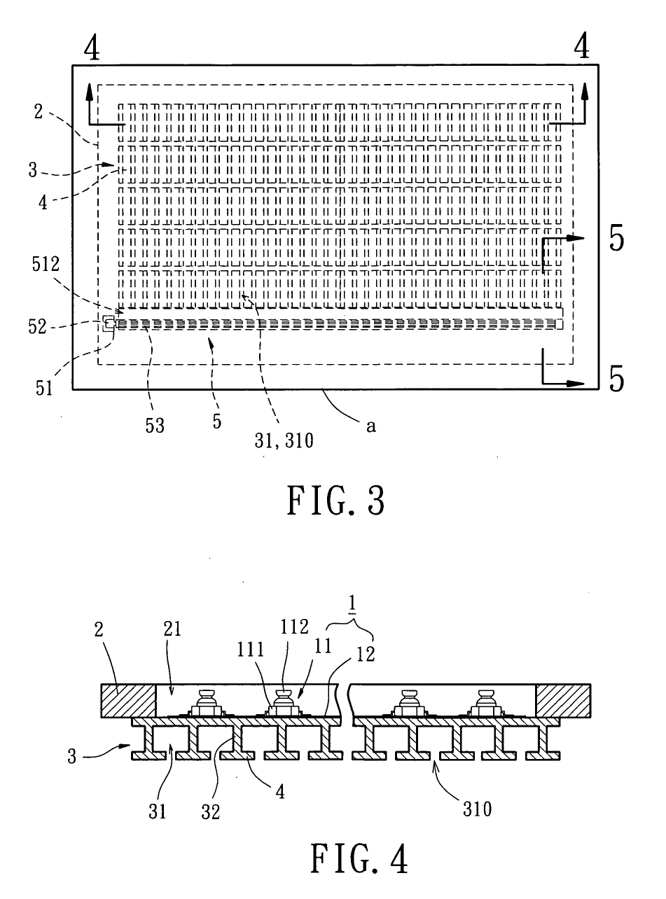

Constructions of the frame plate 2 shall be described in detail, with reference to FIGS. 2 and 3. Formed on the frame plate 2 are at least one first assembling window 21 and at least one second assembling window 22. In assembling operation, the frame plate 2 is attached to the heat-dissipating plate 3 in an intended manner. To enhance thermal conductivity, the frame plate 2 is also made from a metal such as aluminum, copper, gold, silver or alloy thereof having a good thermal conductivity. Alternatively, the frame plate 2 may be made from a nonmetal material, such as plastic or foam material. Each of the first assembling window 21 and the second assembling window 22 preferably connects opposite surfaces of the frame plate 2. The first assembling window 21 serves to receive the back light unit 1. In this illustrated embodiment, lengths of the first assembling window 21 and the second assembling window 22 have orientations arranged to extend in the same direction (i.e. longitudinal direction). The second assembling window 22 serves to receive the cross-flow fan system 5. In a preferred embodiment, the second assembling window 22 has a width greater than that of the cross-flow fan system 5 such that the second assembling window 22 can provide an air inlet space (unlabelled) formed therein.

Constructions of the heat-dissipating plate 3 and the cover plates 4 shall be described in detail, with continued reference to FIGS. 2 and 3. The heat-dissipating plate 3 is also made from a metal such as aluminum, copper, gold, silver or alloy thereof having a good thermal conductivity. The heat-dissipating plate 3 has a rear surface to form a plurality of thermal-exchanging channels 31 and a plurality of heat-dissipating fins 32. Each of the thermal-exchanging channels 31 is formed between any two of the adjacent heat-dissipating fins 32. Furthermore, each of the thermal-exchanging channels 31 has an air inlet end and an air outlet end opposite thereto. In this illustrated embodiment, the thermal-exchanging channels 31 and the heat-dissipating fins 32 extend in a direction perpendicular to a longitudinal direction of the cross-flow fan system 5. Accordingly, the ends (i.e. air inlet ends) of the thermal-exchanging channels 31 are substantially adjacent to and aligned with the cross-flow fan system 5.

To provide a better efficiency of heat dissipation, there is provided a set of the cover plates 4 which are helpful in thermal exchange. A total surface area of the heat-dissipating plate 3 is further increased. Preferably, the cover plates 4 are provided on the rear surface of the heat-dissipating plate 3 so as to cover thermal-exchanging channels 31. Each of the cover plates 4 has a predetermined width. In this illustrated embodiment, the cover plates 4 are integrally formed on top portions of the corresponding heat-dissipating fins 32. Consequently, a convectional slit 310 is formed between any two of the adjacent cover plates 4, and can be designed to have a preferred width according to design needs. The convectional slit 310 may be functioned to dissipate heats once the operation of the cross-flow fan system 5 stops or terminates during use.

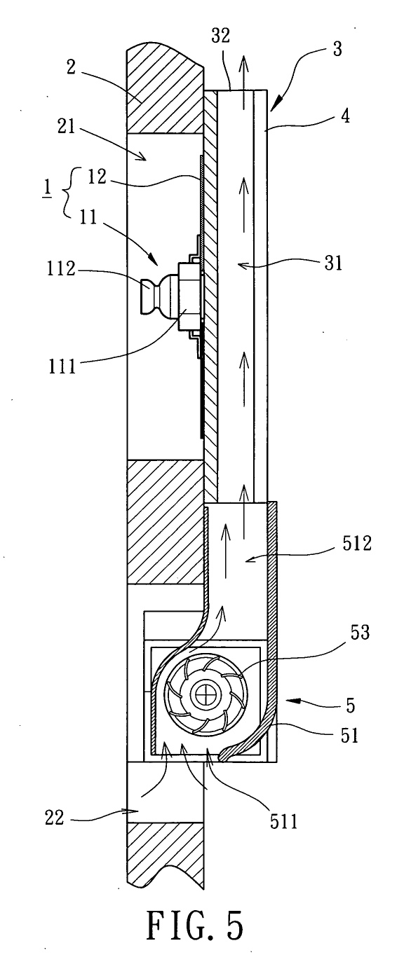

Referring now to FIGS. 2 and 5, construction of the cross-flow fan system 5 shall be described in detail. In this preferred embodiment, the cross-flow fan system 5 includes a housing 51, a power unit 52 and a blower fan 53. The housing 51 contains the combination of the power unit 52 and the blower fan 53. The power unit 52 is selected from a motor, and is arranged at an end of the blower fan 53 for driving it. Preferably, the housing 51 has an air inlet 511 and an air outlet 512 provided at opposite sides. The air inlet 511 is located in the air inlet space of the second assembling window 22 of the frame plate 2. In operation, the blower fan 53 can drive airflow via the air inlet 511 to pass through an interior of the housing 51, and to exhaust it from the air outlet 512. The air outlet 512 is arranged to connect with the air inlet ends of the thermal-exchanging channels 31 when the cross-flow fan system 5 is installed on the frame plate 2. When the blower fan 53 rotates, the airflow enters the air inlet ends and travels to the air outlet ends of the thermal-exchanging channels 31. Consequently, the operation of the blower fan 53 exhausts the airflow from the air outlet ends of the thermal-exchanging channels 31 to the ambient environment.

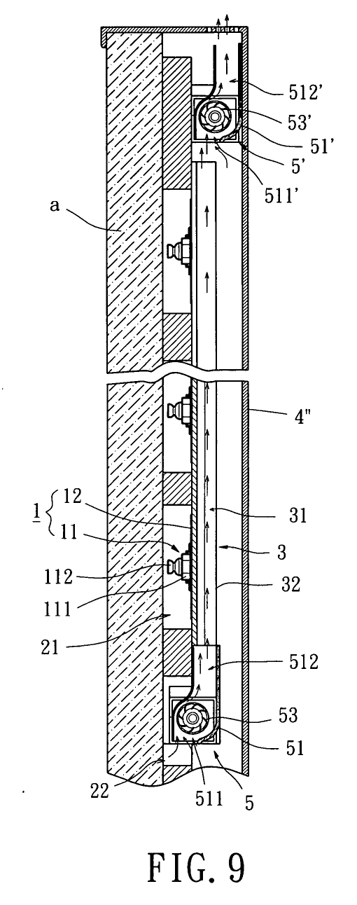

Referring now to FIGS. 2 through 5, when the flat panel display is operated, the light component 112 of the backlighting unit 11 emits lights to penetrate a flat panel identified as “a” (as best shown in FIG. 9) to display images and generates waste heats therefrom. Subsequently, the mounting seat 111 rapidly transmits the waste heats due to the good thermal-conductive material of the mounting seat 111. A bottom of the mounting seat 111 can directly conducts the waste heats to the heat-dissipating plate 3.

With continued reference to FIGS. 2 through 5, when the good thermal-conductive material of the heat-dissipating plate 3 is heated, the heats can be dissipated from surfaces of the thermal-exchanging channels 31 and the heat-dissipating fins 32 to the ambient environment. Synchronously, the cross-flow fan system 5 can continuously supply a desired amount of cooling air to enter the air inlet ends of the thermal-exchanging channels 31 for thermal exchanging operation such that the cooling air is heated in the thermal-exchanging channels 31. The cooling air is forced to travel along the thermal-exchanging channels 31, as indicated by the direction arrows in FIG. 5. Finally, the heated air is exhausted from the convectional slits 310 or the air outlet ends of the thermal-exchanging channels 31. There is a high degree of thermal exchange of the combined backlighting and heat-dissipating module since the air outlet 512 of the cross-flow fan system 5 is aligned with the air inlet ends of the thermal-exchanging channels 31. It is apparent that no additional fan unit or liquid circulating pipe is applied in practicing the combined backlighting and heat-dissipating module in accordance with the first embodiment of the present invention. Advantageously, the combined backlighting and heat-dissipating module carries out a higher efficiency of heat dissipation.

On the other hand, each of the cover plates 4 is integrally formed on the top portion of the corresponding heat-dissipating fin 32. Although some of the heated air may be exhausted from the convectional slits 310 of the thermal-exchanging channels 31, the other may still be exhausted from the air outlet ends of the thermal-exchanging channels 31. The convectional slit 310 formed between any two of the adjacent cover plates 4 is helpful in adjusting an air pressure in the thermal-exchanging channel 31. In this illustrated embodiment, the cross-flow fan system 5 is arranged at the bottom side of the heat-dissipating plate 3 and the thermal-exchanging channels 31 are arranged to extend in the vertical direction so that the heated air may automatically rise in the thermal-exchanging channels 31. Advantageously, such an arrangement of the combined backlighting and heat-dissipating module carries out a higher efficiency of heat dissipation.

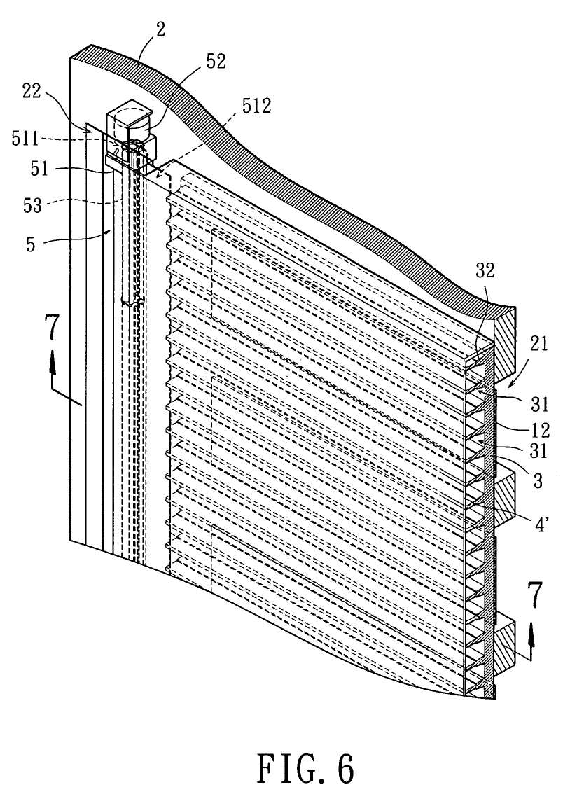

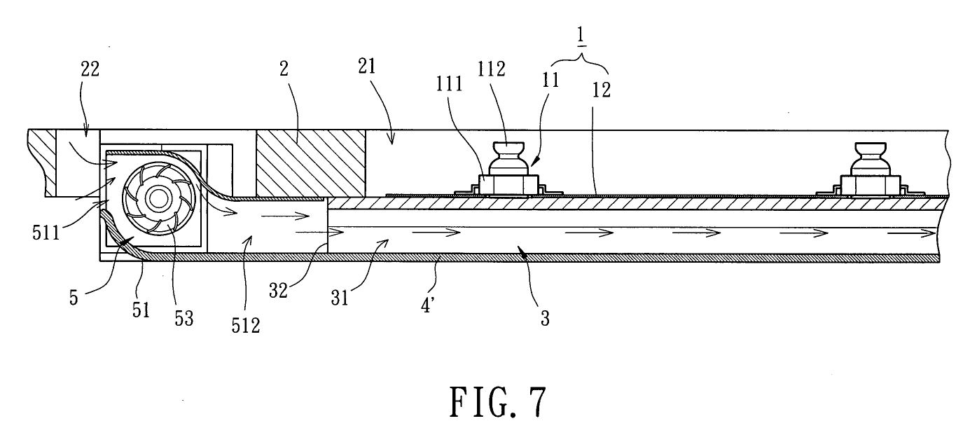

Turning now to FIGS. 6 and 7, a fragmental perspective view and a cross-sectional view of the combined backlighting and heat-dissipating module in accordance with the second embodiment of the present invention are illustrated. In comparison with the first embodiment, the heat-dissipating plate 3 of the second embodiment arranged to have the thermal-exchanging channels 31 extending in a horizontal direction. The second assembling window 22 of the frame plate 2 is arranged at one of left and right ends of the first assembling window 21. The second assembling window 22 extends in a longitudinal direction perpendicular to that of the first assembling window 21. In this manner, the cross-flow fan system 5 received in the second assembling window 22 is installed on one of right and left sides of the heat-dissipating plate 3 which is received in the first assembling window 21. The cross-flow fan system 5 is aligned with the air inlet ends of the thermal-exchanging channels 31. In this illustrated embodiment, the top cover 4′ is a “one-piece” member integrally formed on the housing 51 of the cross-flow fan system 5 so as to simplify the entire structure of the combined backlighting and heat-dissipating module. Once assembled, the top cover 4′ cover the top portions of the heat-dissipating fins 32 of the heat-dissipating plate 3. In a preferred embodiment, the top cover 4′ is extended from the air outlet 512 of the cross-flow fan system 5. Consequently, the cooling air supplied from the air outlet 512 of the cross-flow fan system 5 directly enters the air inlet ends of the thermal-exchanging channels 31 and exhausts from the air outlet ends.

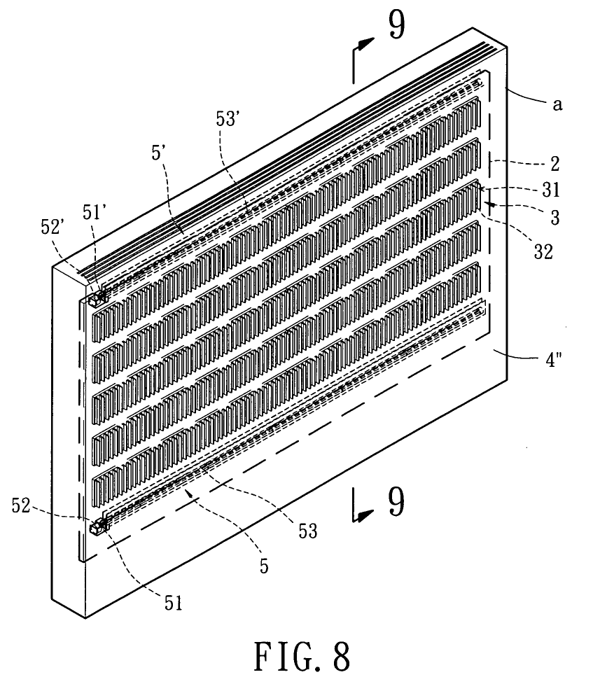

Turning now to FIGS. 8 and 9, a fragmental perspective view and a cross-sectional view of the combined backlighting and heat-dissipating module in accordance with the third embodiment of the present invention are illustrated. In comparison with the first embodiment, the combined backlighting and heat-dissipating module of the third embodiment further includes a cross-flow fan system 5′ in addition to the cross-flow fan system 5. The cross-flow fan system 5′ is arranged at the air outlet ends of the thermal-exchanging channels 31 while the cross-flow fan system 5 is arranged at the air inlet ends of the thermal-exchanging channels 31. In an alternative embodiment, the cross-flow fan system 5′ is received in another assembling window 23 of the frame plate 2. The ends (i.e. air outlet ends) of the thermal-exchanging channels 31 are substantially adjacent to and aligned with the air inlet 511′ of the cross-flow fan system 5′.

Furthermore, the combined backlighting and heat-dissipating module of the third embodiment further includes the cover plate 4″ arranged at a rear side thereof. The cover plate 4″ is selected from a rear cover of the flat panel display. Preferably, the heat-dissipating fins 32 of the heat-dissipating plate 3 do not provide either of the top plate or the convectional slit 310. In a preferred embodiment, the rear cover plate 4″ may be spaced apart from the top portions of the heat-dissipating fins 32 of the heat-dissipating plate 3. In heat dissipating operation, the cooling airflows driven by the cross-flow fan systems 5, 5′ enters the air inlet ends of the thermal-exchanging channels 31 and exhausts from the air outlet ends.

In the third embodiment, the cross-flow fan system 5 drives the cooling air to enter the air inlet ends of the thermal-exchanging channels 31. Synchronously, the heated air from the air outlet ends of the thermal-exchanging channels 31 is sucked into the air inlet 511′ of the cross-flow fan system 5′ and is exhausted from the air outlet 512′ of the cross-flow fan system 5′. Consequently, the thermal-exchanging channels 31 of the heat-dissipating plate 3 can be designed to have a greater length.

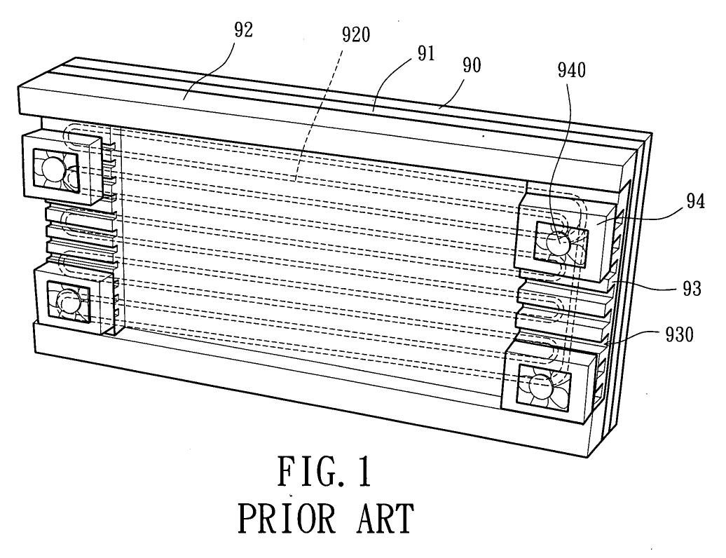

As has been discussed above, the heat-dissipating fans 94 of the conventional heat-dissipating backlighting module cannot drive a cooling airflow to pass through a center portion of the heat-dissipating plate 92 where the temperature is even relatively high, as shown in FIG. 1. Disadvantageously, an increased amount of noise will occur when there are a greater number of the heat-dissipating fans 94 arranged and operated in the heat-dissipating backlighting module. Conversely, the cross-flow fan system 5 of the present invention is arranged at the air inlet ends of the thermal-exchanging channels 31 formed on the rear surface of the heat-dissipating plate 3, as best shown in FIG. 2. Advantageously, the cross-flow fan system 5 can drive a cooling airflow to directly enter the air inlet ends of the thermal-exchanging channels 31, and to exhaust the heated air from the air outlet ends of the thermal-exchanging channels 31 so as to enhance the efficiency of heat dissipation. In addition to this, the cover plates 4 are integrally formed on the heat-dissipating fins 32 such that the cover plates 4 are helpful in dissipating heats of the heat-dissipating plate 3. In the first embodiment, the convectional slit 310 of the thermal-exchanging channel 31 is formed between any two of the adjacent cover plates 4, and some of the heated air may be exhausted from the convectional slits 310 of the thermal-exchanging channels 31. Advantageously, the convectional slit 310 formed between any two of the adjacent cover plates 4 is helpful in adjusting an air pressure in the thermal-exchanging channel 31. In the second embodiment, the cover plate 4 is integrally formed on the housing 51 of the cross-flow fan system 5 so as to simplify the entire structure of the combined backlighting and heat-dissipating module. In the third embodiment, the two cross-flow fan systems 5, 5′ are arranged at the opposite ends of the thermal-exchanging channels 31 respectively so as to enhance the efficiency of heat dissipation.

Although the invention has been described in detail with reference to its presently preferred embodiment, it will be understood by one of ordinary skill in the art that various modifications can be made without departing from the spirit and the scope of the invention, as set forth in the appended claims.

What is claimed is:

1. A combined backlighting and heat-dissipating module for use in a flat panel display, comprising:
at least one heat-dissipating plate having a front surface on which to attach a back light unit, and a rear surface to provide a plurality of thermal-exchanging channels and a plurality of heat-dissipating fins, each of the thermal-exchanging channels being formed between any two of the adjacent heat-dissipating fins;
at least one cover plate arranged on a top portion of the heat-dissipating fin; and
at least one cross-flow fan system arranged to align with one end of the thermal-exchanging channels;
wherein the cross-flow fan system drives a cooling airflow to enter air inlet ends of the thermal-exchanging channels and to exhaust from air outlet ends of the thermal-exchanging channels.

2. The combined backlighting and heat-dissipating module for use in the flat panel display as defined in claim 1, wherein the cross-flow fan system has an air outlet aligned with the air inlet ends of the thermal-exchanging channels when assembled.

3. The combined backlighting and heat-dissipating module for use in the flat panel display as defined in claim 1, wherein the cross-flow fan system has an air inlet aligned with the air outlet ends of the thermal-exchanging channels when assembled.

4. The combined backlighting and heat-dissipating module for use in the flat panel display as defined in claim 1, wherein the cover plates are provided and integrally formed on the heat-dissipating fins such that any two of the adjacent cover plates define a convectional slit.

5. The combined backlighting and heat-dissipating module for use in the flat panel display as defined in claim 1, wherein the top cover is integrally formed on the housing of the cross-flow fan system.

6. The combined backlighting and heat-dissipating module for use in the flat panel display as defined in claim 1, wherein the cover plate is selected from a rear cover of the flat panel display.

7. The combined backlighting and heat-dissipating module for use in the flat panel display as defined in claim 1, further comprising a frame plate attached to the front surface of the heat-dissipating plate, the frame plate including at least one first assembling window to receive the back light unit, and at least one second assembling window to receive the cross-flow fan system.

8. The combined backlighting and heat-dissipating module for use in the flat panel display as defined in claim 7, wherein the first assembling window and the second assembling window are extend in a longitudinal direction.

9. The combined backlighting and heat-dissipating module for use in the flat panel display as defined in claim 7, wherein the second assembling window extends in a longitudinal direction perpendicular to that of the first assembling window.

10. The combined backlighting and heat-dissipating module for use in the flat panel display as defined in claim 1, wherein the cross-flow fan system includes a power unit and a blower fan, the power unit being arranged at an end of the blower fan.

11. A combined backlighting and heat-dissipating module for use in a flat panel display, comprising:
at least one heat-dissipating plate having a front surface on which to attach a back light unit, and a rear surface to provide a plurality of thermal-exchanging channels and a plurality of heat-dissipating fins, each of the thermal-exchanging channels being formed between any two of the adjacent heat-dissipating fins;
a first cross-flow fan system having an air outlet arranged to align with first ends of the thermal-exchanging channels; and
a second cross-flow fan system having an air inlet arranged to align with second ends of thermal-exchanging channels;
wherein the first cross-flow fan system drives a cooling airflow to enter thermal-exchanging channels while the second cross-flow fan system sucks and exhausts the cooling airflow from the thermal-exchanging channels.

12. The combined backlighting and heat-dissipating module for use in the flat panel display as defined in claim 11, further comprising one or more of cover plates arranged at top portions of the heat-dissipating fins.

13. The combined backlighting and heat-dissipating module for use in the flat panel display as defined in claim 12, wherein the cover plates integrally formed on the heat-dissipating fins such that any two of the adjacent cover plates define a convectional slit.

14. The combined backlighting and heat-dissipating module for use in the flat panel display as defined in claim 12, wherein the top cover is integrally formed on the housing of the cross-flow fan system.

15. The combined backlighting and heat-dissipating module for use in the flat panel display as defined in claim 12, wherein the cover plate is selected from a rear cover of the flat panel display.

16. The combined backlighting and heat-dissipating module for use in the flat panel display as defined in claim 11, further comprising a frame plate attached to the front surface of the heat-dissipating plate.

17. The combined backlighting and heat-dissipating module for use in the flat panel display as defined in claim 16, wherein the frame plate including at least one first assembling window to receive the back light unit, and at least one second assembling window to receive the cross-flow fan system.

18. The combined backlighting and heat-dissipating module for use in the flat panel display as defined in claim 17, wherein the first assembling window and the second assembling window are extend in a longitudinal direction.

19. The combined backlighting and heat-dissipating module for use in the flat panel display as defined in claim 17, wherein the second assembling window extends in a longitudinal direction perpendicular to that of the first assembling window.

20. The combined backlighting and heat-dissipating module for use in the flat panel display as defined in claim 11, wherein the cross-flow fan system includes a power unit and a blower fan, the power unit being arranged at an end of the blower fan.
